(19) United States
(12) Patent Application Publication
(10) Pub. No.: US 2026/0188631 A1
(43) Pub. Date: Jul. 2, 2026

(54) Plasma Processing Device and Plasma Measuring Method

(71) Applicant: Tokyo Electron Limited, Tokyo (JP)

(72) Inventors: Kenta KATO, Yamanashi (JP); Taro IKEDA, Yamanashi (JP); Kazushi KANEKO, Yamanashi (JP); Eiki KAMATA, Yamanashi (JP)

(21) Appl. No.: 19/542,333

(22) Filed: Feb. 17, 2026

Related U.S. Application Data
(63) Continuation of application No. PCT/JP2024/028948, filed on Aug. 14, 2024.

(30) Foreign Application Priority Data
Aug. 28, 2023 (JP) 2023-138318

(51) Int. Cl. H01J 37/32; G01R 19/00

(52) U.S. Cl. CPC H01J 37/32917; G01R 19/0046; H01J 2237/24564

(57) ABSTRACT

A plasma processing apparatus comprises a processing chamber providing a processing space, an electromagnetic wave generator configured to generate plasma in the processing space by supplying electromagnetic waves, a first dielectric body having a first surface facing the processing space, an electromagnetic wave supply part configured to supply the electromagnetic waves to the processing space via the first dielectric body and a resonator array structure along the first surface of the first dielectric body. The resonator array structure includes resonators that are capable of resonating with a magnetic field component of the electromagnetic waves and have a size smaller than a wavelength of the electromagnetic waves. The resonators have a structure in which C-shaped ring members made of a conductor are provided on one surface of a dielectric plate. At least one of the C-shaped ring members serves as a probe for measuring information on the plasma.

### CROSS-REFERENCE TO RELATED APPLICATIONS

This application is a bypass continuation application of International Application No. PCT/JP2024/028948 having an international filing date of Aug. 14, 2024 and designating the United States, the International Application being based upon and claiming the benefit of priority from Japanese Patent Application No. 2023-138318 filed on Aug. 28, 2023, the entire contents of which are incorporated herein by reference.

### TECHNICAL FIELD

The present disclosure relates to a plasma processing apparatus and a plasma measuring method.

### BACKGROUND

The plasma processing apparatus disclosed in International Publication No. WO 2023/032725 includes a processing chamber, an electromagnetic wave generator, and a resonator array structure. The processing chamber provides a processing space. The electromagnetic wave generator generates electromagnetic waves for plasma excitation, which are supplied to the processing space. The resonator array structure is formed by arranging a plurality of resonators capable of resonating with the magnetic field component of the electromagnetic waves and having a size smaller than the wavelength of the electromagnetic waves. The resonator array structure is located in the processing chamber.

### SUMMARY

The present disclosure provides a plasma processing apparatus and a plasma measuring method capable of quantitatively evaluating plasma generated via a resonator array structure in its vicinity.

A plasma processing apparatus in accordance with one aspect of the present disclosure comprises a processing chamber providing a processing space, an electromagnetic wave generator configured to generate plasma in the processing space by supplying electromagnetic waves, a first dielectric body having a first surface facing the processing space, an electromagnetic wave supply part configured to supply the electromagnetic waves to the processing space via the first dielectric body, and a resonator array structure located in the processing chamber along the first surface of the first dielectric body. The resonator array structure includes a plurality of resonators that are capable of resonating with a magnetic field component of the electromagnetic waves and have a size smaller than a wavelength of the electromagnetic waves. The plurality of resonators has a structure in which C-shaped ring members made of a conductor are provided on one surface of a dielectric plate. At least one of the C-shaped ring members serves as a probe for measuring information on the plasma.

### BRIEF DESCRIPTION OF THE DRAWINGS

FIG. 1 is a schematic cross-sectional view showing an example of a configuration of a plasma processing apparatus according to an embodiment of the present disclosure.

FIG. 2 is a plan view showing an example of a configuration of a dielectric window and a resonator array according to the embodiment, which is viewed from below.

FIG. 3 is a diagram showing an example of a configuration of a card-shaped resonator according to the embodiment.

FIG. 4 is a diagram showing an example of a configuration of a card-shaped resonator according to the embodiment.

FIG. 5 is a diagram showing another example of the configuration of the card-shaped resonator according to the embodiment.

FIG. 6 is a diagram showing an example of a cross-section of the card-shaped resonator according to the embodiment.

FIG. 7 is a diagram showing an example of a configuration of a card-shaped resonator also serving as a probe according to the embodiment.

FIG. 8 is a diagram showing an example of a cross-section of the card-shaped resonator also serving as a probe according to the embodiment.

FIG. 9 is a diagram showing an example of the relationship between an S21 value of a card-shaped resonator and a microwave frequency.

FIG. 10 is a perspective view showing an example of a resonator array structure according to the embodiment.

FIG. 11 is a plan view showing an example of cell arrangement in a resonator array structure according to the embodiment, which is viewed from below.

FIG. 12 is a perspective view showing an example of a base plate according to the embodiment.

FIG. 13 is a cross-sectional view showing an example of a XIII-XIII cross section of FIG. 12.

FIG. 14 is a cross-sectional view showing an example of an XIV-XIV cross section of FIG. 10.

FIG. 15 is a diagram showing an example of combination of a probe and plasma in a cell space.

FIG. 16 is a diagram showing an example of combination of a probe and plasma in a cell space.

FIG. 17 is a diagram showing an example of an equivalent circuit for plasma measurement using an insulating probe.

FIG. 18 is a diagram showing an example of a Fourier series expansion result of a measured current value.

FIG. 19 is a flowchart showing an example of a plasma measuring process according to the embodiment.

### DETAILED DESCRIPTION

Hereinafter, embodiments of a plasma processing apparatus and a plasma measuring method of the present disclosure will be described in detail with reference to the accompanying drawings. Further, the following embodiments are not intended to limit the present disclosure.

In a plasma processing apparatus using microwaves for plasma excitation, the power of the microwaves supplied into the processing chamber may be increased in order to increase the electron density of the plasma. The electron density of the plasma may increase as the power of the microwaves supplied into the processing chamber increases.

Here, it is known that when the electron density of the plasma reaches a certain upper limit by increasing the power of the microwaves supplied into the processing chamber, the dielectric constant of the space in the processing chamber becomes negative. The upper limit of the electron density is appropriately referred to as “cutoff density.” In addition, the refractive index is known as an index indicating whether or not microwaves can propagate through space. The refractive index N is expressed by the following Eq. (1):

$$N = √ ε √ μ , \qquad Eq . ( 1 )$$

wherein ε indicates a dielectric constant, and μ indicates a magnetic permeability.

In general, the magnetic permeability is a positive value. Therefore, when the dielectric constant of the space in the processing chamber becomes a negative value, the refractive index of the space in the processing chamber becomes a pure imaginary number according to the above Eq. (1). Accordingly, microwaves are attenuated and cannot propagate through the space in the processing chamber. As described above, when the plasma electron density reaches the cutoff density, the microwaves cannot propagate in the space in the processing chamber and, thus, the microwave power is not sufficiently absorbed by the plasma. As a result, the increase in the density of the plasma produced in the processing chamber over a wide area is hindered.

Therefore, it is expected that high-density plasma can be generated over a wide range, and the plasma generated via a resonator array structure (hereinafter, also referred to as meta-material) is quantitatively evaluated in its vicinity.

### [Configuration of Plasma Processing Apparatus]

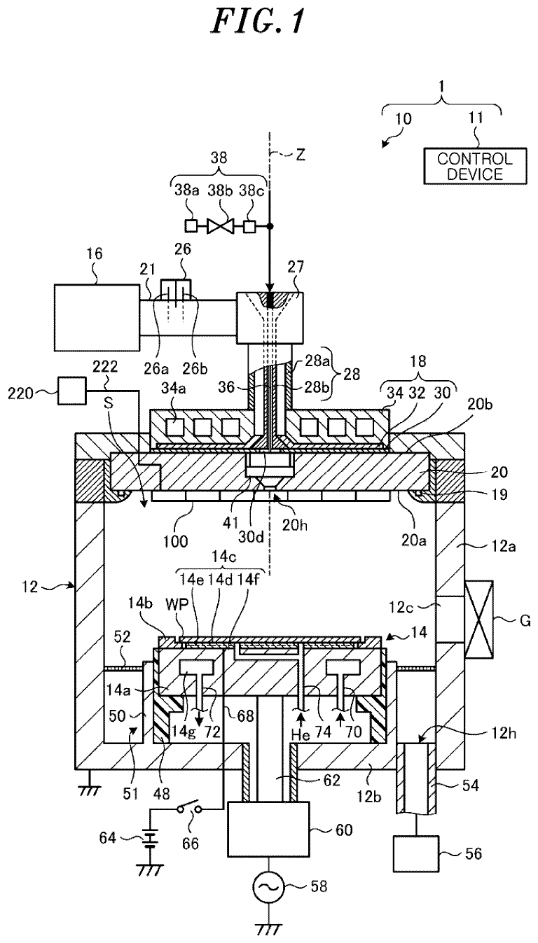

FIG. 1 is a schematic cross-sectional view showing an example of a configuration of a plasma processing apparatus according to an embodiment of the present disclosure. The plasma processing apparatus 1 includes an apparatus main body 10 and a control device 11. The apparatus main body 10 includes a processing chamber 12, a stage 14, a microwave output device (an example of an electromagnetic wave generator) 16, an antenna 18, a dielectric window 20, a resonator array structure 100, and a measuring part 220.

The processing chamber 12 is formed in a substantially cylindrical shape, and is made of, e.g., aluminum having an anodically oxidized surface. The processing chamber 12 provides a substantially cylindrical processing space S therein. The processing chamber 12 is frame-grounded. Further, the processing chamber 12 has a sidewall 12a and a bottom portion 12b. The central axis of the sidewall 12a is defined as an axis Z. The bottom portion 12b is located at the lower end of the sidewall 12a. An exhaust port 12h for exhaust is provided at the bottom portion 12b. The upper end of the sidewall 12a is opened. The inner wall surface of the sidewall 12a faces the processing space S. In other words, the sidewall 12a is installed with the inner wall surface facing the processing space S.

The sidewall 12a is provided with an opening 12c for loading and unloading a target object WP. The opening 12c is opened and closed by a gate valve G.

A dielectric window 20 is provided at the upper end of the sidewall 12a, and closes the opening at the upper end of the sidewall 12a from the top. The bottom surface (an example of a first surface) 20a of the dielectric window 20 (an example of a first dielectric body) faces the processing space S. In other words, the dielectric window 20 is installed with the bottom surface 20a facing the processing space S. An O-ring 19 is located between the dielectric window 20 and the upper end of the sidewall 12a.

The stage 14 is accommodated in the processing chamber 12. The stage 14 is provided to face the dielectric window 20 in the direction of the axis Z. The space between the stage 14 and the dielectric window 20 serves as the processing space S. The target object WP is placed on the stage 14.

The stage 14 has a base 14a and an electrostatic chuck 14c. The base 14a is formed in a substantially disc shape, and is made of a conductive material such as aluminum or the like. The base 14a is located in the processing chamber 12 such that its central axis substantially coincides with the axis Z.

The base 14a is supported by a cylindrical support 48 made of an insulating material and extending in the direction of the axis Z. A conductive cylindrical support 50 is provided at the outer periphery of the cylindrical support 48. The cylindrical support 50 extends from the bottom portion 12b of the processing chamber 12 toward the dielectric window 20 along the outer periphery of the cylindrical support 48. An annular exhaust line 51 is formed between the cylindrical support 50 and the sidewall 12a.

An annular baffle plate 52 having a plurality of through-holes formed in a thickness direction is provided at the upper part of the exhaust line 51. The above-described exhaust port 12h is provided below the baffle plate 52. An exhaust device 56 having a vacuum pump such as a turbomolecular pump and an automatic pressure control valve is connected to the exhaust port 12h via an exhaust line 54. The exhaust device 56 can reduce a pressure in the processing space S to a desired vacuum level.

The base 14a functions as a high-frequency electrode. A high-frequency power supply 58 for RF bias is electrically connected to the base 14a via a power supply rod 62 and a matching unit 60. The high-frequency power supply 58 supplies a bias power of a predetermined frequency (e.g., 13.56 MHz) suitable for controlling the energy of ions attracted to the target object WP to the base 14a via the matching unit 60 and the power supply rod 62.

The matching unit 60 accommodates a matching device for matching the impedance of the high-frequency power supply 58 side with the impedance of the load, mainly the electrode, the plasma, and the processing chamber 12. A blocking capacitor for generating a self-bias is included in the matching device.

The electrostatic chuck 14c is provided on the upper surface of the base 14a. The electrostatic chuck 14c attracts and holds the target object WP by an electrostatic force. The electrostatic chuck 14c has a substantially disc-shaped outer shape, and includes an electrode 14d, an insulating film (dielectric film) 14e, and an insulating film (dielectric film) 14f. The electrostatic chuck 14c is located on the upper surface of the base 14a such that the central axis of the electrostatic chuck 14c substantially coincides with the axis Z. The electrode 14d of the electrostatic chuck 14c is made of a conductive film, and is located between the insulating film 14e and the insulating film 14f. The electrode 14d is electrically connected to a DC power supply 64 via a coated wire 68 and a switch 66. The electrostatic chuck 14c can attract and hold the target object WP on the upper surface by an electrostatic force generated by a DC voltage applied from the DC power supply 64. The upper surface of the electrostatic chuck 14c serves as a placing surface on which the target object WP is placed and faces the processing space S. In other words, the electrostatic chuck 14c is installed with the placing surface facing the processing space S. Further, an edge ring 14b is provided on the base 14a. The edge ring 14b is located to surround the target object WP and the electrostatic chuck 14c. The edge ring 14b may also be referred to as “focus ring.”

A channel 14g is provided in the base 14a. A coolant is supplied to the channel 14g from a chiller unit (not shown) via a line 70. The coolant supplied to the channel 14g is returned to the chiller unit via a line 72. The temperature of the base 14a is controlled by circuiting the coolant of which temperature is controlled by the chiller unit through the channel 14g of the base 14a. By controlling the temperature of the base 14a, the temperature of the target object WP on the electrostatic chuck 14c on the base 14a is controlled via the electrostatic chuck 14c on the base 14a.

Further, a line 74 for supplying a heat transfer gas, such as He gas, to the gap between the upper surface of the electrostatic chuck 14c and the backside of the target object WP is formed in the stage 14.

The microwave output device 16 outputs microwaves (an example of electromagnetic waves) for exciting the processing gas supplied to the processing chamber 12. The microwave output device 16 can adjust the frequency, the power, and the bandwidth of the microwaves. The microwave output device 16 can generate microwaves including a single frequency component by setting the bandwidth of the microwaves to about 0, for example. Moreover, the microwave output device 16 can generate microwaves (hereinafter, appropriately referred to as “broadband (BB) microwaves”) including a plurality of frequency components belonging to a predetermined frequency bandwidth. The power of the plurality of frequency components may be the same, or only the central frequency component in the band may have a power greater than the power of the other frequency components. The microwave output device 16 can adjust the power of the microwaves within a range of 0 W to 5000 W, for example. The microwave output device 16 can adjust the frequency of the microwaves or the central frequency of the BB microwaves within a range of 2.3 GHZ to 2.5 GHZ, for example, and can adjust the bandwidth of the BB microwaves within a range of 0 MHz to 100 MHz, for example. Further, the microwave output device 16 can adjust the frequency pitch (carrier pitch) of the plurality of frequency components of the BB microwaves within a range of 0 KHz to 25 kHz, for example.

Further, the apparatus main body 10 includes a waveguide 21, a tuner 26, a mode converter 27, and a coaxial waveguide 28. The output part of the microwave output device 16 is connected to one end of the waveguide 21. The other end of the waveguide 21 is connected to the mode converter 27. The waveguide 21 is a rectangular waveguide, for example. The tuner 26 is located in the waveguide 21. The tuner 26 has movable plates 26a and 26b. By adjusting the protruding amounts of the movable plates 26a and 26b with respect to the inner space of the waveguide 21, the impedance of the microwave output device 16 and the impedance of the load can be matched.

The mode converter 27 converts the mode of the microwaves outputted from the waveguide 21, and supplies the microwaves after the mode conversion to the coaxial waveguide 28. The coaxial waveguide 28 includes an outer conductor 28a and an inner conductor 28b. The outer conductor 28a and the inner conductor 28b have a substantially cylindrical shape. The outer conductor 28a and the inner conductor 28b are located above the antenna 18 such that the central axes of the outer conductor 28a and the inner conductor 28b substantially coincide with the axis Z. The coaxial waveguide 28 transmits the microwaves of which mode has been converted by the mode converter 27 to the antenna 18.

The antenna 18 supplies microwaves into the processing chamber 12. The antenna 18 is an example of an electromagnetic wave supply part. The antenna 18 is located on the upper surface 20b of the dielectric window 20, and supplies microwaves to the processing space S through the dielectric window 20. The antenna 18 includes a slot plate 30, a dielectric plate 32, and a cooling jacket 34. The slot plate 30 is formed in a substantially circular plate shape, and is made of a conductive metal. The slot plate 30 is located on the upper surface 20b of the dielectric window 20 such that the central axis of the slot plate 30 coincides with the axis Z. A plurality of slot holes are formed in the slot plate 30. The plurality of slot holes form a plurality of slot pairs, for example. Each of the plurality of slot pairs includes two slot holes formed in the shape of long holes extending in directions intersecting each other. The plurality of slot pairs are arranged along one or more concentric circles around the central axis of the slot plate 30. Further, a through-hole 30d through which a conduit 36 to be described later can pass is formed at the center of the slot plate 30.

The dielectric plate 32 is formed in a substantially disc shape, and is made of a dielectric material such as quartz or the like. The dielectric plate 32 is located on the slot plate 30 such that the central axis of the dielectric plate 32 substantially coincides with the axis Z. The cooling jacket 34 is located on the dielectric plate 32. The dielectric plate 32 is located between the cooling jacket 34 and the slot plate 30.

The cooling jacket 34 has a conductive surface. A channel 34a is formed in the cooling jacket 34. A coolant is supplied to the channel 34a from a chiller unit (not shown). The lower end of the outer conductor 28a is electrically connected to the upper surface of the cooling jacket 34. The lower end of the inner conductor 28b is electrically connected to the slot plate 30 through an opening formed in the center of the cooling jacket 34 and the dielectric plate 32.

The microwaves propagating through the coaxial waveguide 28 propagate through the dielectric plate 32, and then are radiated into the processing space S through the dielectric window 20 from the plurality of slot holes of the slot plate 30.

The resonator array structure 100 is formed by arranging a plurality of resonators that can resonate with the magnetic field component of microwaves and have a size smaller than the wavelength of the microwaves. The resonator array structure 100 is located in the processing chamber 12.

Since the resonator array structure 100 is located in the processing chamber 12, the microwaves supplied to the processing space S by the antenna 18 can resonate with the plurality of resonators of the resonator array structure 100. Due to the resonance between the microwaves and the plurality of resonators, the microwaves can be efficiently supplied to the processing space S of the processing chamber 12 and the magnetic permeability of the processing space S can become negative. When the magnetic permeability of the processing space S is negative, even if the electron density of the plasma produced in the processing space S reaches the cutoff density and the dielectric constant of the processing space S is negative, the refractive index becomes a real number according to the above Eq. (1), so that the microwaves can propagate in the processing space S. Accordingly, even if the electron density of the plasma produced in the processing space S reaches the cutoff density, the microwaves can propagate beyond the skin depth of the plasma, and the microwave power can be efficiently absorbed by the plasma. As a result, high-density plasma can be generated over a wide range beyond the skin depth of the plasma. In other words, in accordance with the plasma processing apparatus 1 of the present embodiment, the resonator array structure 100 is located in the processing chamber 12, so that the density of the plasma can be increased over a wide range.

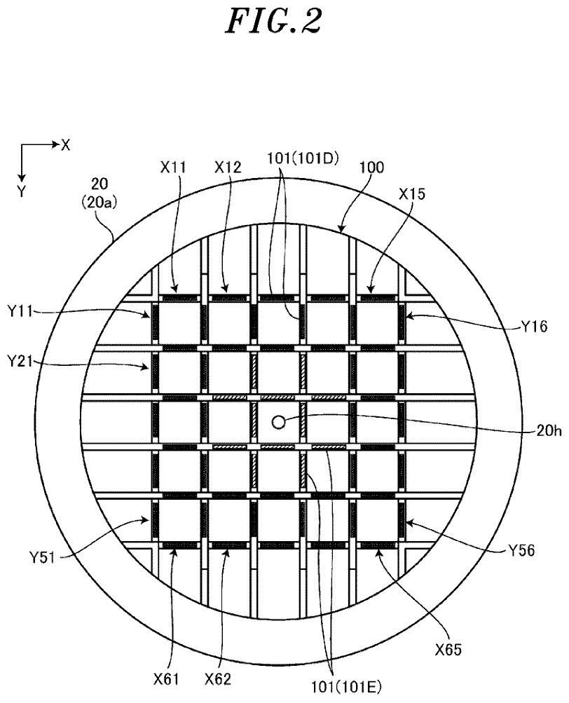

The specific configuration of the resonator array structure 100 will be described with reference to FIGS. 1 and 2. FIG. 2 is a plan view showing an example of the configuration of the dielectric window 20 and resonator array structure 100 according to the present embodiment, which is viewed from below. In FIG. 2, the bottom surface 20a of the dielectric window 20 is formed in a disc shape.

As shown in FIGS. 1 and 2, the resonator array structure 100 is located along the bottom surface 20a of the dielectric window 20.

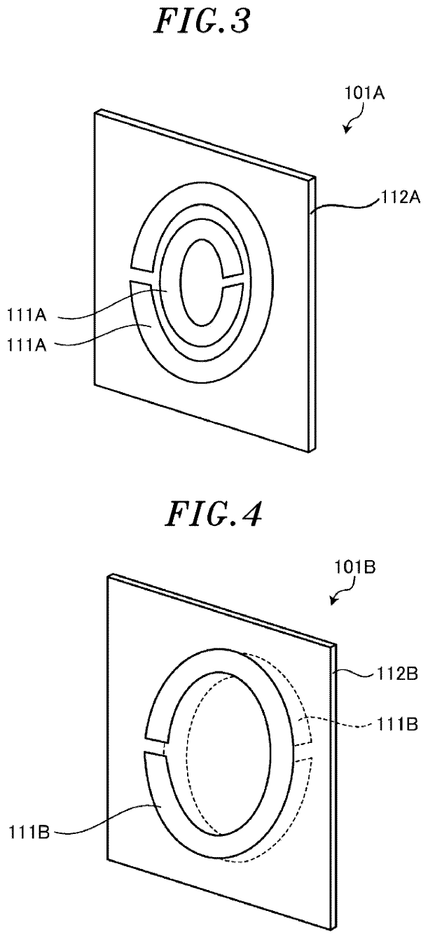

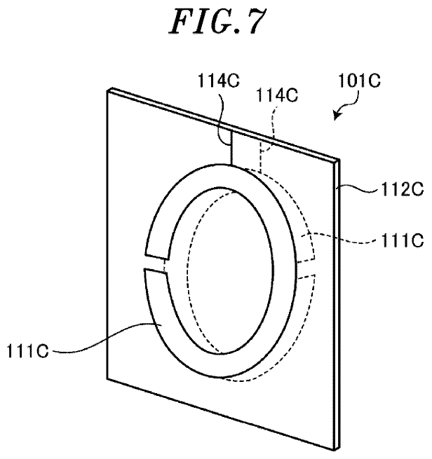

The resonator array structure 100 is formed by arranging a plurality of resonators 101, each being capable of resonating with the magnetic field component of microwaves and having a size smaller than the wavelength of the microwaves, in a lattice shape. Specifically, the plurality of resonators 101 includes at least one of a resonator 101A and a resonator 101B shown in FIGS. 3 and 4. Further, at least one of the plurality of resonators 101 includes a resonator 101C shown in FIG. 7. Each of the plurality of resonators 101 constitutes a series resonant circuit including a capacitor equivalent element and a coil equivalent element. The series resonant circuit is realized by patterning a conductor on the plane.

FIG. 3 shows an example of the configuration of the card-shaped resonator 101A according to the embodiment. The card-shaped resonator 101A shown in FIG. 3 has a structure in which two C-shaped ring members 111A made of a conductor and arranged in a concentric shape in opposite directions are provided on one surface of a dielectric plate 112A. Capacitor equivalent elements are formed on the opposing surfaces of the inner ring member 111A and the outer ring member 111A, or at both ends of each ring member 111A. Coil equivalent elements are formed along the ring members 111A. Accordingly, the resonator 101A can constitute a series resonant circuit.

FIG. 4 is a diagram showing an example of the configuration of the card-shaped resonator 101B according to the embodiment. The card-shaped resonator 101B shown in FIG. 4 has a structure in which a dielectric plate 112B is provided between two C-shaped ring members 111B made of conductors and arranged to be adjacent to each other in opposite directions. In other words, in the resonator 101B, the dielectric plate 112B is embedded between the two C-shaped ring members 111B arranged in opposite directions. The capacitor equivalent element is formed on the opposing surfaces of the two C-shaped ring member 111B, or is formed at both ends of each ring member 111B. The coil equivalent element is formed along each ring member 111B. Accordingly, the resonator 101B can constitute the series resonance circuit. Further, the card-shaped resonator 101B may be formed in a card shape for each pair of two C-shaped ring members 111B.

Further, in the resonator 101B shown in FIG. 4, the number of arrangement (hereinafter, also referred to as “the number of lamination”) of the ring members 111B is two. However, the number of lamination of the ring members 111B may be greater than two. FIG. 5 shows another example of the configuration of the card-shaped resonator 101B according to the embodiment. The resonator 101B shown in FIG. 5 has a structure in which the dielectric plate 112B is provided between N (N≥2)-number of C-shaped ring members 111B made of conductors and arranged adjacent to each other in opposite directions. Even with this structure, the resonator 101B can constitute the series resonance circuit.

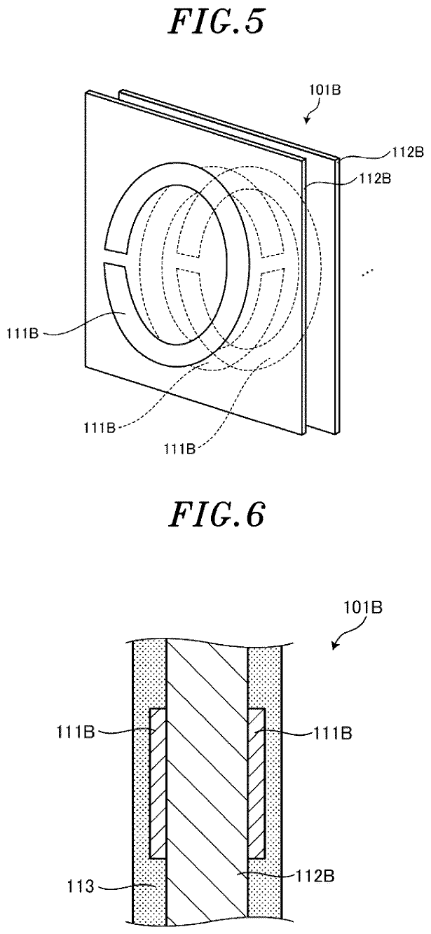

Further, an insulating coating film may be formed on each of the plurality of resonators 101. FIG. 6 shows an example of the cross section of the resonator 101B according to the embodiment. FIG. 6 shows the side cross section of the resonator 101B shown in FIG. 4. An insulating coating film (an example of a second dielectric body) 113 is formed on the surface of the resonator 101B. The coating film 113 is made of, e.g., ceramic. The thickness of the coating film 113 is, e.g., within a range of 0.001 mm to 2 mm. By forming the insulating coating film 113 on each of the plurality of resonators 101, the occurrence of abnormal discharge in each of the plurality of resonators 101 can be suppressed.

Further, in each of the plurality of resonators 101, at least one of the C-shaped ring members may also serve as a probe for measuring plasma information. Conventionally, plasma was measured using, e.g., a probe attached to the sidewall of the chamber. However, in the resonator array structure 100, plasma is generated locally in each cell to be described later, which makes it difficult to quantitatively monitor the degree of control of the plasma. Therefore, in the present embodiment, a C-shaped ring member serves as a probe, thereby quantitatively monitoring the plasma generated via the resonator array structure 100 in its vicinity.

FIG. 7 shows an example of a configuration of a card-shaped resonator 101C, which also serves as a probe, according to the embodiment. The resonator 101C shown in FIG. 7 has a structure in which a dielectric plate 112C is provided between two C-shaped ring members 111C made of a conductor and arranged to be adjacent to each other in opposite directions. In other words, in the resonator 101C, the dielectric plate 112C is embedded between the two C-shaped ring members 111C arranged in opposite directions. The capacitor equivalent element is formed on the opposing surfaces of the two C-shaped ring members 111C, or is formed at both ends of each ring member 111C. The coil equivalent element is formed along each ring member 111C. Accordingly, the resonator 101C can constitute a series resonant circuit. Further, a wiring 114C is connected to each of the two C-shaped ring members 111C. The wiring 114C extends to the end surface of the resonator 101C, and can be connected to a wiring 122 on a base plate 120, which will be described later, on the end surface. Further, the card-shaped resonator 101C can be formed in a card shape for each pair of two C-shaped ring members 111C. Further, the resonator 101C corresponds to the resonator 101B provided with the wiring 114C.

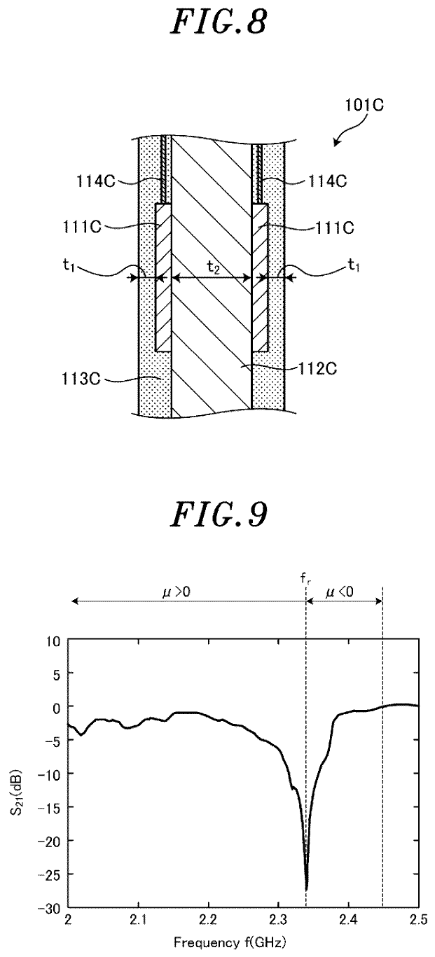

FIG. 8 shows an example of the cross-section of the card-shaped resonator 101C, which also serves as a probe, according to the embodiment. FIG. 8 shows the side cross section of the resonator 101C shown in FIG. 7. An insulating coating film 113C (an example of a second dielectric body) is formed on the surface of the resonator 101C. The coating film 113C is made of, e.g., ceramic. The thickness of the coating film 113C is within a range of 0.001 mm to 2 mm, for example. Here, if the thickness of the coating film 113C is set as a thickness t₁ and the thickness of the dielectric plate 112C is set as a thickness t₂, in the resonator 101C, the thicknesses of the dielectric plate 112C and the coating film 113C are determined to satisfy the relationship of the thickness t₁<<the thickness t₂. Further, the thickness t₂ of the dielectric plate 112C is preferably 100 times or more the thickness t₁ of the coating film 113C. As a result, the two C-shaped ring members 111C function as insulating probes connected to the wiring 114C to measure plasma on the coating film 113C side. In other words, the dielectric plate 112C is embedded between the two C-shaped ring members 111C of the resonator 101C, and the dielectric plate 112C is considerably thicker than the coating film 113C, so that the impedance between the two C-shaped ring members 111C becomes high. In other words, the influence of the C-shaped ring member 111C as a probe on the dielectric plate 112C side is reduced.

In other words, the C-shaped ring members 111C are formed on both surfaces of the dielectric plate 112C, and are covered with the coating film 113C that is the second dielectric body. Further, the thickness of the dielectric plate 112C between the C-shaped ring members 111C formed on both surfaces of the dielectric plate 112C is greater than the thickness of the coating film 113C that is the second dielectric body that covers the C-shaped ring member 111C. Further, the thickness of the dielectric plate 112C is 100 times or more the thickness of the coating film 113C that is the second dielectric body.

Referring back to FIG. 1, a conduit 36 is provided inside the inner conductor 28b of the coaxial waveguide 28. A through-hole 30d through which the conduit 36 can pass is formed at the center of the slot plate 30. The conduit 36 extends through the inner conductor 28b to be connected to a gas supply part 38.

The gas supply part 38 supplies a processing gas for processing the target object WP to the conduit 36. The gas supply part 38 includes a gas supply source 38a, a valve 38b, and a flow rate controller 38c. The gas supply source 38a is a processing gas supply source. The valve 38b controls the supply and stop of supply of the processing gas from the gas supply source 38a. The flow rate controller 38c is, e.g., a mass flow controller, and controls the flow rate of the processing gas from the gas supply source 38a.

The apparatus main body 10 includes an injector 41. The injector 41 supplies a gas from the conduit 36 to a through-hole 20h formed in the dielectric window 20. The gas supplied to the through-hole 20h in the dielectric window 20 is injected into the processing space S, and is excited by the microwaves supplied from the antenna 18 to the processing space S through the dielectric window 20. Accordingly, the processing gas is turned into plasma in the processing space S, and the target object WP is processed by ions and radicals contained in the plasma.

Further, the apparatus main body 10 includes the measuring part 220. The measuring part 220 is connected to the C-shaped ring member 111C also serving as an insulating probe through a wiring 222 (including wirings 122 and 114C to be described later). The measuring part 220 includes a power supply part that applies an AC voltage to the C-shaped ring member 111C also serving as an insulating probe through the wirings 222 and the wirings 122 and 114C (to be described later), and an ammeter that measures the current value flowing through the C-shaped ring member 111C. The power supply part is controlled to apply a low-frequency AC voltage of, e.g., 100 KHz or less, and a low voltage of several volts to the C-shaped ring member 111C. In other words, the AC voltage applied from the power supply part is a frequency and voltage that does not affect the operation of the resonator array structure 100. Further, the measuring part 220 may include a low-pass filter and a band-stop filter to suppress the influence of electromagnetic waves supplied from the microwave output device 16.

The measuring part 220 calculates an electron temperature Tₑ and an electron density nₑ based on the measured current value. The measuring part 220 outputs the calculated electron temperature Tₑ and electron density nₑ to the control device 11. Further, the measuring part 220 may output the measured current value to the control device 11, and the control device 11 may calculate the electron temperature Tₑ and the electron density nₑ. The calculated electron temperature Tₑ and electron density nₑ can be used for feedback control of the microwave output device 16. For example, since the resonator 101 has a sensitive response to the electromagnetic wave frequency, the control device 11 controls the microwave output device 16 to adjust the electromagnetic wave frequency while monitoring the calculated electron temperature Tₑ and electron density nₑ, i.e., the plasma status.

The control device 11 includes a processor, a memory, and an input/output interface. The memory stores programs, process recipes, and the like. The processor reads a program from the memory and executes it, thereby collectively controlling individual components of the apparatus main body 10 via the input/output interface based on the process recipe stored in the memory.

The control device 11 controls the microwaves supplied to the processing space S by the antenna 18 and the resonators 101 to resonate in a target frequency band higher than the resonant frequency of the resonators 101 when plasma is generated in the processing space S. Here, the resonant frequency is, e.g., a frequency at which the transmission characteristic value (e.g., S21 value) of the resonators 101 becomes minimum.

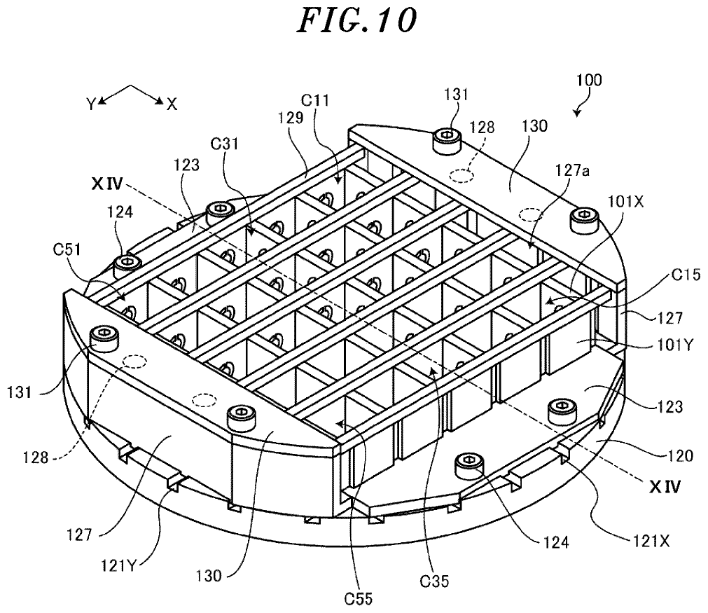

FIG. 9 shows an example of the relationship between the S21 value of the card-shaped resonator and the microwave frequency. When the frequency of the microwaves supplied to the processing space S by the antenna 18 is equal to the resonant frequency fr (about 2.35 GHZ) of the resonators 101, the S21 value of the resonators 101 becomes minimum, and the resonance between the microwaves and the resonators 101 occurs. The resonance between the microwaves and the plurality of resonators 101 is maintained even in a predetermined frequency band (e.g., about 0.1 GHZ) higher than the resonant frequency fr of the plurality of resonators 101. In a predetermined frequency band higher than the resonance frequency fr of the plurality of resonators 101, both the dielectric constant and the magnetic permeability of the processing space S can become negative due to the resonance between the microwaves and the plurality of resonators 101. As can be seen from the above Eq. (1), the microwaves can propagate in the processing space S. The target frequency band of the present embodiment is set to a predetermined frequency band (e.g., about 0.1 GHZ) higher than the resonance frequency fr of the plurality of resonators 101. It is preferable that the target frequency band is, e.g., within 0.05 times the resonance frequency fr of the plurality of resonators 101. Further, the resonant frequency fr of the card-shaped resonator 101 can be measured, e.g., using a vector network analyzer in which a transmitting/receiving antenna is located in a direction parallel to the ring member 111B of the card-shaped resonator 101B.

The relationship of the resonance frequency, the refractive index, the permittivity, and the magnetic permeability regarding the propagation of electromagnetic waves to multiple resonators was reported by D. R. Smith, D. C. Vier, Th. Koschny and C. M. Soukoulis in “Electromagnetic parameter retrieval from inhomogeneous meta-materials” of “PHYSICAL REVIEW E 71, 036617 (2005).”

By resonating the microwaves and the plurality of resonators 101 in a target frequency band higher than the resonance frequency fr of the plurality of resonators 101, the microwaves can propagate beyond the skin depth of the plasma even when the electron density of the plasma reaches the cutoff density. Therefore, the microwave power can be efficiently absorbed by the plasma. As a result, it is possible to generate high-density plasma over a wide range beyond the skin depth of the plasma. In other words, in the plasma processing apparatus 1 of the present embodiment, the plasma density can be increased over a wide range by resonating the microwaves and the plurality of resonators 101 in a target frequency band higher than the resonance frequency fr of the plurality of resonators 101.

### [Specific Description of Resonator Array Structure]

Next, the resonator array structure 100 will be described in detail. As shown in FIG. 2, the resonator array structure 100 is formed by arranging the card-shaped resonators 101 in a lattice pattern. Further, in the following description, the resonator array structure 100 may also be referred to as “meta-material 100” and the card-shaped resonators 101 may also be referred to as “meta-atoms 101.” In the example shown in FIG. 2, the meta-atoms 101 are arranged such that the cells surrounded by the meta-atoms 101 form five columns in the X-axis direction and five rows in the Y-axis direction. In other words, the meta-atoms 101 are arranged in six rows and five columns, such as X11, X12, . . . , X15, . . . , X61, X62, . . . , X65, with the longitudinal directions along the X-axis direction. The meta-atoms 101 are arranged in five rows and six columns, such as Y11, Y21, . . . , Y51, . . . , Y16, Y26, . . . , Y56, with the longitudinal directions along the Y-axis direction. Further, the lattice opening width and the lattice depth of the cell are greater than or equal to the outer dimensions of the C-shaped ring member (e.g., the ring member 111B) of the meta-atom 101.

Further, the through-hole 20h is located in the cell located at the center of the meta-material 100. In the case of controlling the plasma density, the meta-atoms 101D constituting the peripheral cells and the meta-atoms 101E near the cells of the through-holes 20h may have different resonant frequencies fr. For example, the meta-atom 101D has the resonant frequency fr (about 2.35 GHZ). Further, for example, the meta-atom 101E has the resonant frequency fr (about 2.25 GHz or about 2.55 GHZ) deviated from the resonant frequency fr of the meta-atom 101D by a predetermined frequency (e.g., ±0.2 GHZ).

FIG. 10 is a perspective view showing an example of a resonator array structure according to the present embodiment. In FIG. 10, the meta-material 100 is illustrated upside down. Further, in FIG. 10, ring members are depicted on some meta-atoms 101 to make the orientation of the meta-atoms 101 clear. However, in actual cases, the surface is covered with a dielectric (insulating film).

The meta-material 100 shown in FIG. 10 has the base plate 120. The base plate 120 is made of a dielectric material such as quartz or ceramic. The base plate 120 has a plurality of grooves 121X in the X-axis direction and a plurality of grooves 121Y in the Y-axis direction, each serving as a groove for fitting the meta-atoms 101.

The meta-atoms 101 are fitted into the grooves 121X and 121Y. In the following description, the meta-atom 101 fitted into the groove 121X may be referred to as “meta-atom 101X” and the meta-atom 101 fitted into the grooves 121Y may be referred to as “meta-atom 101Y.” Further, it is assumed that the meta-atom 101X has a width greater than that of the meta-atom 101Y, and the ends of the meta-atoms 101X are in contact with each other. Each area surrounded by the meta-atom 101X and the meta-atom 101Y is a cell. In the example of FIG. 10, five rows and five columns of cells C11 to C55 are formed. Side surface pressing members 123 are fixed to the base plate 120 using screws 124 to be in contact with one surfaces of the meta-atoms 101Y at the arrangement Y11 to Y51 and Y16 to Y56 shown in FIG. 2 among the outermost meta-atoms 101. Further, the side surface pressing members 123 and the screws 124 are examples of the pressing member, and are made of ceramic such as alumina or the like, which is a dielectric material.

Side surface pressing members 127 are fixed to the base plate 120 using screws 128 to be in contact with one surfaces of the meta-atoms 101X at the arrangement X11 to X15 and X61 to X65 shown in FIG. 2 among the outermost meta-atoms 101. A space 127a is formed between the side surface pressing members 127 and the outermost meta-atom 101X. The space 127a is provided in consideration of plasma generation. Further, the side surface pressing members 127 and the screws 128 are an example of the pressing member, and are made of a ceramic such as alumina or the like, which is a dielectric material.

Pressing members 129 press the meta-atoms 101X and 101Y between the two side surface pressing members 127. The pressing members 129 are located between the two side surface pressing members 127 to press the upper parts of the meta-atoms 101Y continuously in the longitudinal direction and to press the upper ends of the meta-atoms 101X. In other words, the pressing members 129 are located parallel to the side pressing members 123. The pressing members 129 are made of a ceramic such as alumina or the like, which is a dielectric material.

Members 130 are located above the side pressing members 127 to fix the pressing members 129. The ends of the pressing members 129 are fitted between the side pressing members 127 and the members 130. The members 130 are fixed to the side pressing members 127 by screws 131. The members 130 and the screws 131 are examples of the pressing member, and are made of a ceramic, such as alumina or the like, which is a dielectric material.

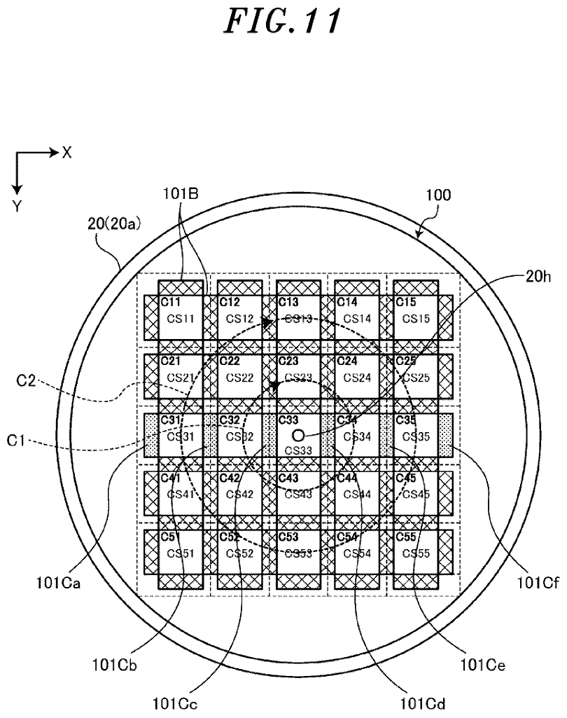

Next, the arrangement of the resonators (meta-atoms) 101C in the cells C11 to C55 and the wiring will be described with reference to FIGS. 11 to 14. FIG. 11 is a plan view showing an example of the cell arrangement of the resonator array structure according to the present embodiment, which is viewed from below. As shown in FIG. 11, the cells C11 to C25 and the cells C41 to C55 are surrounded on all four sides by the meta-atoms (resonators) 101B. In the cells C31 to C35, the meta-atoms (resonators) 101C are arranged in the Y-axis direction, and the meta-atoms 101B are arranged in the X-axis direction. In other words, the meta-atoms 101Ca to 101Cf are arranged at the arrangement Y31 to Y36, respectively, as shown in FIG. 2. Further, the meta-atoms 101B and 101C shown in FIG. 11 may be either the meta-atom 101D or the meta-atom 101E shown in FIG. 2 in terms of the resonant frequency. Further, the meta-atom 101C may be located at the cell C33 and any cell through which any one of the circumferences C1 or C2 passes.

For example, the cell where the meta-atoms 101C are arranged may be the combination of the cells C31 and C33, or the combination of cells C32 and C33. Further, the cells C11 to C55 define cell spaces CS11 to CS55 that are plasma generation spaces.

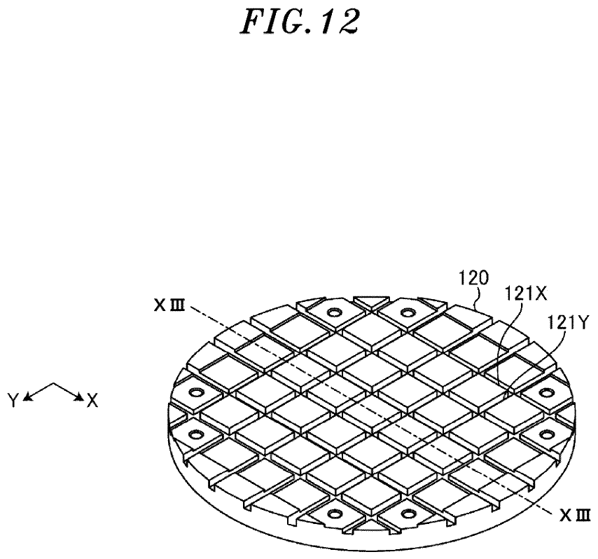

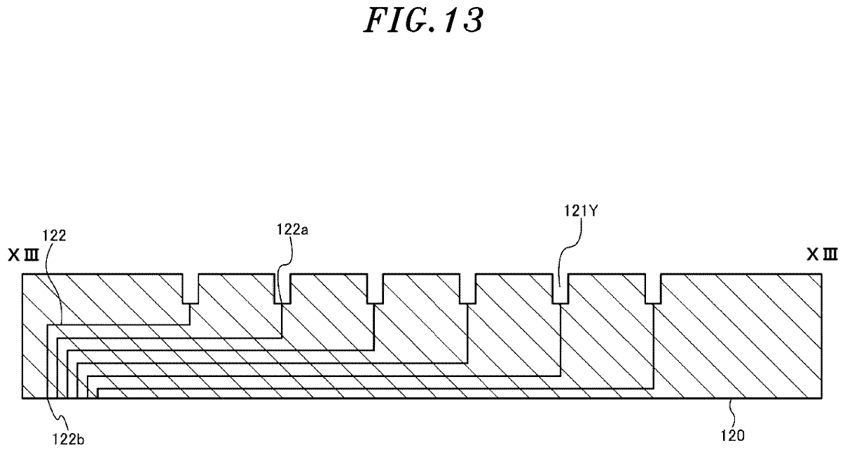

FIG. 12 is a perspective view showing an example of a base plate according to the present embodiment. FIG. 13 is a cross-sectional view showing an example of the XIII-XIII cross section of FIG. 12. As shown in FIGS. 12 and 13, in the B-B cross section of the base plate 120, conductors 122a are provided at the bottom portions of the grooves 121Y where the meta-atoms 101Ca to 101Cf are located. Each conductor 122a is connected to each wiring 122. Each wiring 122 is connected to the measuring part 220 through each connection portion 122b and each wiring 222.

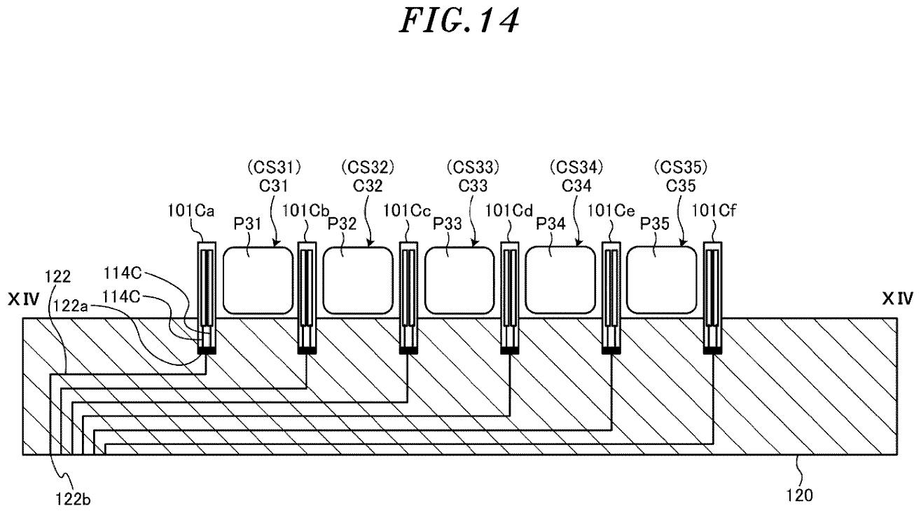

FIG. 14 is a cross-sectional view showing an example of the A-A cross section of FIG. 10. In FIG. 14, components other than the base plate 120 and the meta-atoms 101Ca to 101Cf are omitted. Further, FIG. 14 shows an upside-down state relative to FIG. 1. FIG. 14 shows a state in which plasmas P31 to P35 are generated in the cell spaces CS31 to CS35 of the cells C31 to C35 in the A-A cross section. In this case, in the meta-atom 101Ca, information on the plasma P31 is measured using one C-shaped ring member 111C. In other words, in the meta-atom 101Ca, an AC voltage is applied from the measuring part 220 through the wiring 222, the connection portion 122b, the wiring 122, the conductor 122a, and the wiring 114C, and the current flowing through one C-shaped ring member 111C is measured. Further, in the other C-shaped ring member 111C, the space outside the cell C31 is measured.

In the meta-atom 101Cb, information on the plasma P31 is measured using one C-shaped ring member 111C, and information on the plasma P32 is measured using the other C-shaped ring member 111C. Similarly, in the meta-atoms 101Cc to 101Ce, information on plasmas P32 to P34 is measured using one C-shaped ring member 111C, and information on plasmas P33 to P35 is measured using the other C-shaped ring member 111C. Similarly to the meta-atom 101Ca, in the meta-atom 101Cf, information on the plasma P35 is measured using one C-shaped ring member 111C. Further, in the other C-shaped ring member 111C of the meta-atom 101Cf, the space outside the cell C35 is measured.

### [Measurement Using Probe]

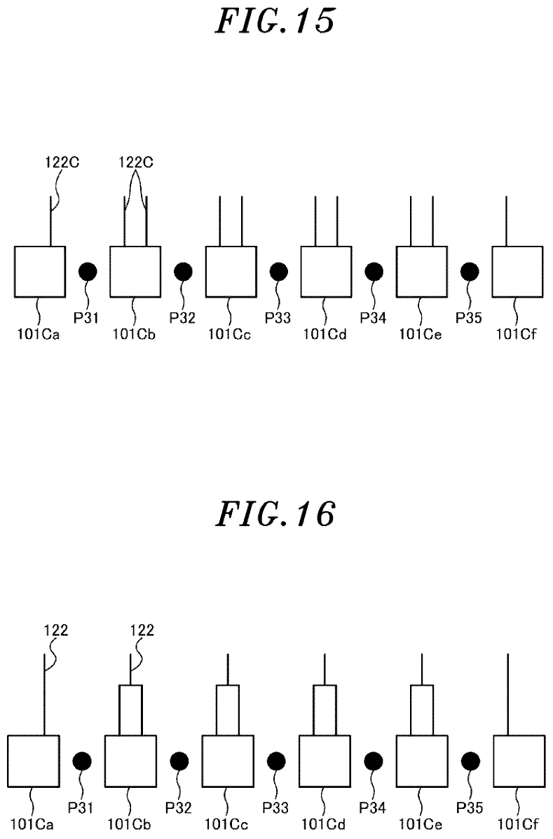

Here, the combination of a probe and plasma in the cell space will be described with reference to FIGS. 15 and 16. FIGS. 15 and 16 show an example of combination of a probe and plasma in the cell space. FIG. 15 shows a case in which the wirings 114C of the meta-atoms 101Ca to 101Cf are independently connected to the measuring part 220. In this case, for example, the information on the plasma P31 is obtained from the wiring 122C connected to the ring member 111C on the plasma P31 side of the meta-atom 101Ca and the wiring 122C connected to the ring member 111C on the plasma P31 side of the meta-atom 101Cb. Since these two probes (the ring members 111C) measure the same plasma P31, the information on the plasma P31 is obtained based on the average value of the current values. Similarly, the information on the plasmas P32 to P35 is obtained based on the average value of the current values. The information on the plasmas P31 to P35 includes the electron temperature Tₑ and the electron density nₑ.

FIG. 16 shows a case in which the two wirings 114C of the meta-atoms 101Cb to 101Ce are connected by the conductor 122a to simplify the wiring, and each wiring 122 is connected to the measuring part 220. In other words, a case in which the wirings 122 described in FIGS. 12 to 14 are used is illustrated. In this case, if the information on the plasmas P31 to P35 is set as unknown x₁ to x₅, and the current values of the probes (the ring members 111C) of the meta-atoms 101Ca to 101Cf are set as current values Ia to If, the following simultaneous Eqs. (2) to (7) can be expressed.

$${x}_{1} = Ia \qquad Eq . ( 2 )$$

$$( {x}_{1} + {x}_{2} ) / 2 = Ib \qquad Eq . ( 3 )$$

$$( {x}_{2} + {x}_{3} ) / 2 = Ic \qquad Eq . ( 4 )$$

$$( {x}_{3} + {x}_{4} ) / 2 = Id \qquad Eq . ( 5 )$$

$$( {x}_{4} + {x}_{5} ) / 2 = Ie \qquad Eq . ( 6 )$$

$${x}_{5} = If \qquad Eq . ( 7 )$$

In this case, for example, in the probe of the meta-atom 101Cb, the current value is measured as the sum of the unknowns x₁ and x₂ of the plasmas P31 and P32 of the adjacent cells C31 and C32. Therefore, a current value Ib is the average value of the unknowns x₁ and x₂, as shown in Eq. (3). This is the same for the meta-atoms 101Cc to 101Ce, so that current values Ic to Ie are the average values of the adjacent cells, as shown in Eqs. (4) to (6).

In other words, the probes are the C-shaped ring members 111C provided on both surfaces of one resonator (meta-atom) 101, and correspond to adjacent cells. Further, the current value is measured as the sum of the values of the adjacent cells. Further, the plasma information, such as the electron temperature Tₑ and the electron density nₑ, is calculated based on the average value calculated from the sum measured by the respective probes in the plurality of resonators 101 facing the respective cells.

Here, the number of equations and the number of unknowns are considered. First, if the number of equations is equal to the number of unknowns, the simultaneous equation is solved. If the number of equations is greater than the number of unknowns (overdetermined system), the simultaneous equation is not solved and, thus, the least-squares method is used to find the solution that best satisfies all equations. If the number of equations is less than the number of unknowns (underdetermined system), the solution to the simultaneous equations is not unique and, thus, the solution with the smallest distance from the origin is estimated to be the solution.

$$( the number of equations = the number of unknowns )$$

For example, if the current value If of the meta-atom 101Cf is not used in FIG. 16, Eqs. (2) to (6) can be used, and the number of equations and the number of unknowns become equal. If the simultaneous equation of Eqs. (2) to (6) is expressed as Ax=b using a square matrix A, the following Eq. (8) is obtained, which can be transformed into Eq. (9). Further, A-1 in this case is expressed as the following Eq. (10). In Eq. (8), the current values Ia to Ie are expressed as a to e. In other words, the unknowns x₁ to x₅ can be calculated from Eqs. (8) to (10), so that the information on the plasmas P31 to P35 can be obtained.

$$( \begin{matrix}1 & 0 & 0 & 0 & 0 \\ \frac{1}{2} & \frac{1}{2} & 0 & 0 & 0 \\ 0 & \frac{1}{2} & \frac{1}{2} & 0 & 0 \\ 0 & 0 & \frac{1}{2} & \frac{1}{2} & 0 \\ 0 & 0 & 0 & \frac{1}{2} & \frac{1}{2}\end{matrix} ) ( \begin{matrix}{x}_{1} \\ {x}_{2} \\ {x}_{3} \\ {x}_{4} \\ {x}_{5}\end{matrix} ) = ( \begin{matrix}a \\ b \\ c \\ d \\ e\end{matrix} ) \qquad Eq . ( 8 )$$

$$x = {A}^{- 1} b \qquad Eq . ( 9 )$$

$${A}^{- 1} = ( \begin{matrix}1 & 0 & 0 & 0 & 0 \\ - 1 & 2 & 0 & 0 & 0 \\ 1 & - 2 & 2 & 0 & 0 \\ - 1 & 2 & - 2 & 2 & 0 \\ 1 & - 2 & 2 & - 2 & 2\end{matrix} ) \qquad Eq . ( 10 )$$

(the number of equations > the number of unknowns (overdetermined system))

For example, when all the current values Ia to If of the meta-atoms 101Ca to 101Cf are used in FIG. 16, Eqs. (2) to (7) are used, so that the number of equations becomes greater than the number of unknowns. If the simultaneous equation of Eqs. (2) to (7) is expressed as Ax=b using the square matrix A, the following Eq. (11) is obtained, which can be transformed into Eq. (12). Further, (A^{T}A)⁻¹A^{T} in this case is referred to as Moore-Penrose inverse matrix, generalized inverse matrix, pseudo-inverse matrix, or the like, and is expressed by the following Eq. (13). In Eq. (11), the current values Ia to If are expressed as a to f. Further, A^{T} in Eq. (12) is the transpose matrix of A. In other words, the unknowns x₁ to x₅ can be calculated from Eqs. (11) to (13), so that the information on the plasmas P31 to P35 can be obtained. Further, obtaining Eq. (12) is mathematically equivalent to estimating the solution by the least-squares method.

$$( \begin{matrix}1 & 0 & 0 & 0 & 0 \\ \frac{1}{2} & \frac{1}{2} & 0 & 0 & 0 \\ 0 & \frac{1}{2} & \frac{1}{2} & 0 & 0 \\ 0 & 0 & \frac{1}{2} & \frac{1}{2} & 0 \\ 0 & 0 & 0 & \frac{1}{2} & \frac{1}{2} \\ 0 & 0 & 0 & 0 & 1\end{matrix} ) ( \begin{matrix}{x}_{1} \\ {x}_{2} \\ {x}_{3} \\ {x}_{4} \\ {x}_{5}\end{matrix} ) = ( \begin{matrix}a \\ b \\ c \\ d \\ e \\ f\end{matrix} ) \qquad Eq . ( 11 )$$

$$x \approx {( {A}^{T} A )}^{- 1} {A}^{T} b \qquad Eq . ( 12 )$$

$${( {A}^{T} A )}^{- 1} {A}^{T} = ( \begin{matrix}\frac{17}{18} & \frac{1}{9} & - \frac{1}{9} & \frac{1}{9} & - \frac{1}{9} & \frac{1}{18} \\ - \frac{13}{18} & \frac{13}{9} & \frac{5}{9} & - \frac{5}{9} & \frac{5}{9} & - \frac{5}{18} \\ \frac{1}{2} & - 1 & 1 & 1 & - 1 & \frac{1}{2} \\ - \frac{5}{18} & \frac{5}{9} & - \frac{5}{9} & \frac{5}{9} & \frac{13}{9} & - \frac{13}{18} \\ \frac{1}{18} & - \frac{1}{9} & \frac{1}{9} & - \frac{1}{9} & \frac{1}{9} & \frac{17}{18}\end{matrix} ) \qquad Eq . ( 13 )$$

(the number of equations < the number of unknowns (underdetermined system))

For example, when the current values Ib through Ie of the meta-atoms 101Cb to 101Ce are used in FIG. 16, Eqs. (3) to (6) are used and, thus, the number of equations becomes less than the number of unknowns. When the simultaneous equation of Eqs. (3) to (6) is expressed as Ax=b using the square matrix A, the following Eq. (14) is obtained, which can be transformed into Eq. (15). Further, A^{T}(AA^{T})⁻¹ in this case is referred to as Moore-Penrose inverse matrix, generalized inverse matrix, pseudo-inverse matrix, or the like, and is expressed by the following Eq. (16). In Eq. (14), the current values Ib to Ie are expressed as b to e. Further, A^{T} in Eq. (15) is the transpose matrix of A. In other words, the unknowns x₁ to x₅ can be calculated from Eqs. (14) to (16), so that the information on the plasmas P31 to P35 can be obtained. Obtaining Eq. (15) is mathematically equivalent to finding the solution with the smallest distance from the origin among all possible solutions. Further, the plasma information can be similarly obtained even when the number of equations is smaller. In other words, the location of the meta-atom 101C, which is the plasma measurement point, may vary without being limited to the location of each meta-atom 101 in the resonator array structure 100.

$$( \begin{matrix}\frac{1}{2} & \frac{1}{2} & 0 & 0 & 0 \\ 0 & \frac{1}{2} & \frac{1}{2} & 0 & 0 \\ 0 & 0 & \frac{1}{2} & \frac{1}{2} & 0 \\ 0 & 0 & 0 & \frac{1}{2} & \frac{1}{2}\end{matrix} ) ( \begin{matrix}{x}_{1} \\ {x}_{2} \\ {x}_{3} \\ {x}_{4} \\ {x}_{5}\end{matrix} ) = ( \begin{matrix}b \\ c \\ d \\ e\end{matrix} ) \qquad Eq . ( 14 )$$

$$x \approx {{A}^{T} ( {AA}^{T} )}^{- 1} b \qquad Eq . ( 15 )$$

$${{A}^{T} ( {AA}^{T} )}^{- 1} = ( \begin{matrix}\frac{8}{5} & - \frac{6}{5} & \frac{4}{5} & - \frac{2}{5} \\ \frac{2}{5} & \frac{6}{5} & - \frac{4}{5} & \frac{2}{5} \\ - \frac{2}{5} & \frac{4}{5} & \frac{4}{5} & - \frac{2}{5} \\ \frac{2}{5} & - \frac{4}{5} & \frac{6}{5} & \frac{2}{5} \\ - \frac{2}{5} & \frac{4}{5} & - \frac{6}{5} & \frac{8}{5}\end{matrix} ) \qquad Eq . ( 16 )$$

[Calculation of Electron Temperature Tₑ and Electron Density nₑ]

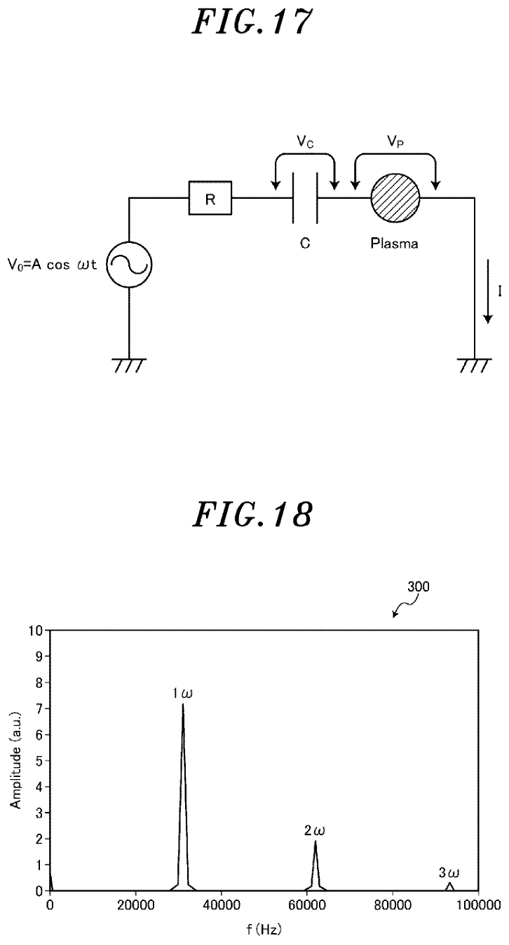

Next, the calculation of the electron temperature Tₑ and the electron density nₑ based on the current measured by the probe will be described. FIG. 17 shows an example of an equivalent circuit for plasma measurement using an insulating probe. As shown in FIG. 17, in the present embodiment, an AC voltage V₀=A cos ωt is applied to the plasma via a resistor R and a capacitor C. Similarly to a Langmuir probe, the insulating probe of the present embodiment utilizes the nonlinearity of the current I relative to a plasma voltage Vₚ. Since the AC voltage V₀ is applied via the capacitor C, it is possible to perform plasma measurement even during a process in which by-products (deposits) that block a DC current are generated. Further, the AC voltage V₀ is measured by the power supply part of the measuring part 220, which applies the AC voltage V₀, and the current I is measured by the ammeter connected in series with the resistance R of the measuring part 220. Here, the current I is expressed by the following Eq. (17). The nonlinearity of the current I relative to the plasma voltage Vₚ is expressed by Eq. (18) that assumes Maxwellian distribution. Eq. (18) yields an equation similar to that for a Langmuir probe. Further, an ion saturation current Iᵢₛ is expressed by the following Eq. (19), and an electron saturation current Iₑₛ is expressed by the following Eq. (20).

$$I = f ( {V}_{p} ) \qquad Eq . ( 17 )$$

$$f ( V ) = {I}_{es} exp ( \frac{{V}_{f} - {ϕ}_{p}}{{T}_{e}} ) exp ( \frac{V}{{T}_{e}} ) - {I}_{is} \qquad Eq . ( 18 )$$

$${I}_{is} = exp ( - \frac{1}{2} ) {en}_{e} S \sqrt{\frac{{eT}_{e}}{{M}_{i}}} \qquad Eq . ( 19 )$$

$${I}_{es} = \frac{1}{4} {en}_{e} S \sqrt{\frac{8 {eT}_{e}}{π {m}_{e}}} \qquad Eq . ( 20 )$$

Here, V_{f} represents a floating potential, φₚ represents a plasma potential, Tₑ represents an electron temperature (eV), nₑ represents an electron density, S represents a probe area, e represents an elementary charge, Mᵢ represents an ion mass, and mₑ represents an electron mass. By applying the amplitude V₀ of the AC voltage V₀ and Eq. (17) to Eq. (18), and using the first type modified Bessel function as shown in the following Eq. (21), the current is decomposed into frequency components as shown in the following Eq. (22).

$$exp ( a cos x ) = {I}_{0} ( a ) + 2 {\sum }_{k = 1}^{∞} {I}_{k} ( a ) cos ( kx ) \qquad Eq . ( 21 )$$

$$I = {I}_{es} exp ( \frac{{V}_{f} - {ϕ}_{p}}{{T}_{e}} ) exp ( \frac{{V}_{0} cos ω t}{{T}_{e}} ) - {I}_{is} = {I}_{es} exp ( \frac{{V}_{f} - {ϕ}_{p}}{{T}_{e}} ) {I}_{0} ( \frac{{V}_{0}}{{T}_{e}} ) - {I}_{is} + 2 {I}_{es} exp ( \frac{{V}_{f} - {ϕ}_{p}}{{T}_{e}} ) {\sum }_{k = 1}^{∞} {I}_{k} ( \frac{{V}_{0}}{{T}_{e}} ) cos ( k ω t ) \qquad Eq . ( 22 )$$

The information on the electron density is contained only in the coefficients (the electron saturation current Iₑₛ) of each frequency component. Therefore, as shown in the following Eq. (23), the electron density nₑ can be deleted from the equation by dividing the first harmonic current by the second harmonic current, thereby calculating the electron temperature Tₑ.

$$\frac{{i}_{1 ω}}{{i}_{2 ω}} = \frac{{I}_{1} ( \frac{{V}_{0}}{{T}_{e}} )}{{I}_{2} ( \frac{{V}_{0}}{{T}_{e}} )} \qquad Eq . ( 23 )$$

The left side of Eq. (23) is the measured value, and represents the ratio of the amplitude of the current i_{1ω} of the fundamental wave 1ω to the amplitude of the current i_{2ω of} the first harmonic 2ω. Further, the right side of Eq. (23) represents the ratio of the fundamental wave (fundamental current) to the first harmonic (second harmonic current) when the current value measured with the insulating probe is expanded using the first type modified Bessel function. Therefore, the electron temperature Tₑ can be calculated using Eq. (23) from the ratio of the measured values and the ratio of the fundamental harmonic to the first harmonic calculated by Fourier series expansion.

Further, the AC component of the current i_{1ω} is expressed by the following Eq. (24).

$${i}_{1 ω} = \frac{1}{2} {en}_{s} {\overline{u}}_{e} S exp ( \frac{{V}_{dc} - {Φ}_{p}}{{T}_{e}} ) {I}_{1} ( \frac{{V}_{0}}{{T}_{e}} ) cos ω t \qquad Eq . ( 24 )$$

Here, ūₑ represents the average velocity of electrons.

Based on the calculated electron temperature Tₑ and the fundamental wave 1ω current i_{1ω}, the electron density nₑ can be calculated using the following Eq. (25).

$${n}_{e} = \frac{{i}_{1 ω}}{2 exp ( - \frac{1}{2} ) eS \sqrt{\frac{{eT}_{e}}{{M}_{i}}}} \frac{{I}_{1} ( \frac{{V}_{0}}{{T}_{e}} )}{{I}_{2} ( \frac{{V}_{0}}{{T}_{e}} )} \qquad Eq . ( 25 )$$

FIG. 18 shows an example of the Fourier series expansion result of the measured current value. Graph 300 in FIG. 18 shows the Fourier series expansion result of the current value measured with an insulating probe. A current flows through the probe in contact with the plasma exponentially with respect to the applied voltage. The current value measured by applying an AC voltage includes, e.g., a component of the fundamental wave 1ω having a fundamental frequency, and a harmonic component such as a first harmonic 2ω having a wavelength twice that of the fundamental wave and a second harmonic 3ω having a wavelength three times higher than that of the fundamental wave. In the example of graph 300, the peak around 31 kHz as the fundamental wave 1ω, the peak around 62 kHz as the first harmonic 2ω, and the peak around 93 kHz as the second harmonic 3ω are included. By performing the Fourier series expansion on the measured current value, the ratio of the fundamental wave 1ω to the first harmonic 2ω can be calculated, as shown in the above Eq. (23).

In other words, in the present embodiment, an AC voltage of a sine wave is applied to the insulating probe (the ring member 111C), and the waveform distorted by the plasma is detected and subjected to the Fourier series expansion, thereby calculating the electron temperature Tₑ and electron density nₑ. For example, in the example shown in FIG. 16, the current values Ia to If measured by the probes (the ring member 111C) of the meta-atoms 101Ca to 101Cf are subjected to the Fourier series expansion, thereby calculating the electron temperature Tₑ and the electron density nₑ as the unknowns x₁ to x₅, respectively.

### [Plasma Measuring Method]

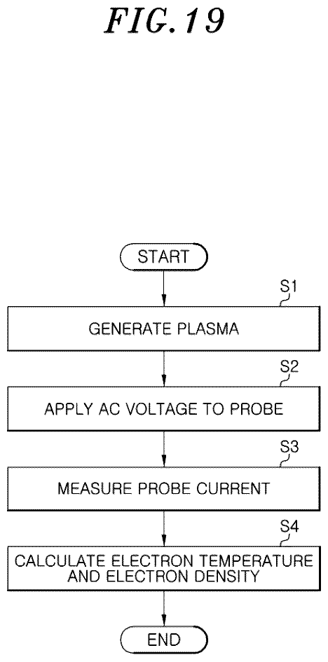

Next, an example of a plasma measuring process in the plasma processing apparatus 1 will be described. FIG. 19 is a flowchart showing an example of a plasma measuring process according to the present embodiment. The plasma measuring process shown in FIG. 19 is realized by the control device 11 that controls the individual components of the apparatus main body 10.

First, the target object WP is loaded into the processing chamber 12 and placed on the electrostatic chuck 14c. Then, the control device 11 opens the valve 38b and controls the flow rate controller 38c such that a predetermined flow rate of the processing gas is supplied into the processing chamber 12. Then, the control device 11 controls the exhaust device 56 to adjust the pressure in the processing chamber 12. Next, the control device 11 controls the microwave output device 16 to supply microwaves from the coaxial waveguide 28 to the processing space S in the processing chamber 12. Accordingly, plasma of the processing gas is generated in the processing chamber 12 (step S1). The plasma processing on the target object WP is performed by the plasma generated in the processing space S in the processing chamber 12.

The control device 11 controls the measuring part 220 to apply an AC voltage to the C-shaped ring member 111C of the meta-atom 101C, which also serves as a probe (step S2). The control device 11 controls the measuring part 220 to measure the current value flowing through the probe (the ring member 111C) (step S3). The control device 11 controls the measuring part 220 to calculate the electron temperature Tₑ and the electron density nₑ based on the measured current value (step S4). The control device 11 acquires the electron temperature Tₑ and the electron density nₑ from the measuring part 220. The control device 11 controls the microwave output device 16 based on the acquired electron temperature Tₑ and electron density nₑ, and controls the plasma by adjusting the frequency of the electromagnetic waves, for example.

Once the plasma processing process is completed, the processed target object WP is removed from the processing chamber 12 by a robot arm (not shown).

As described above, according to the present embodiment, the plasma processing apparatus 1 includes the processing chamber 12, the electromagnetic wave generator (the microwave output device 16), the first dielectric body (the dielectric window 20), the electromagnetic wave supply part (the antenna 18), and the resonator array structure 100. The processing chamber 12 provides the processing space S. The electromagnetic wave generator is configured to supply electromagnetic waves to generate plasma in the processing space. The first dielectric body is provided with the first surface facing the processing space S. The electromagnetic wave supply part is configured to supply electromagnetic waves to the processing space S via the first dielectric body. The resonator array structure 100 is located in the processing chamber 12 along the first surface of the first dielectric body. The resonator array structure 100 includes the plurality of resonators 101 that can resonate with the magnetic field component of the electromagnetic waves and have a size smaller than the wavelength of the electromagnetic waves. The plurality of resonators have a structure in which the C-shaped conductive ring members (the ring members 111A to 111C) are provided on one surface of the dielectric plate (the dielectric plates 112A to 112C). At least one of the C-shaped ring members (the ring member 111C) also serves as a probe for measuring plasma information. As a result, high-density plasma can be generated over a wide area, and the plasma generated by the resonator array structure 100 can be quantitatively evaluated in its vicinity.

Further, the present embodiment further includes the power supply part (the measuring part 220) that applies an AC voltage to the probe (the ring member 111C) via the wiring (the wirings 222, 122, and 114C), and the ammeter (the measuring part 220) that measures the current flowing through the probe. As a result, even plasma generated during plasma processing in which by-products (deposits) are generated can be quantitatively evaluated in its vicinity.

Further, according to the present embodiment, the frequency of the AC voltage is lower than the frequency of the electromagnetic waves supplied from the electromagnetic wave generator to the processing space S. As a result, the measurement AC voltage does not affect plasma generation in the resonator array structure 100.

Further, according to the present embodiment, the frequency of the AC voltage is 100 KHz or less. As a result, the measurement AC voltage does not affect plasma generation in the resonator array structure 100.

Further, according to the present embodiment, the resonator array structure 100 further includes the base plate 120 having the grooves (the grooves 121X and 121Y) on the surface facing the processing space S, and the pressing members (the side surface pressing members 123 and 127, and the pressing member 129) configured to press the plurality of resonators 101, which are fitted vertically into the grooves, toward the base plate 120. The wiring 122 is provided in the grooves and connected to the probe. As a result, the plurality of cells (e.g., the cells C11 to C55) can be formed, and the probe (the ring member 111C) can be positioned to measure the plasma of a specific cell (e.g., the cells C31 to C35).

Further, according to the present embodiment, the C-shaped ring members are formed on both sides of the dielectric plate. As a result, each resonator 101 can form a series resonant circuit.

Further, according to the present embodiment, the C-shaped ring members are coated with the second dielectric body (the coating films 113 and 113C). As a result, abnormal discharge in each resonator 101 can be suppressed.

Further, according to the present embodiment, the C-shaped ring members 111C are formed on both sides of the dielectric plate 112C and are coated with the second dielectric (the coating film 113C). Further, the thickness of the dielectric plate 112C between the C-shaped ring members 111C formed on both sides of the dielectric plate 112C is greater than the thickness of the second dielectric body covering the C-shaped ring members 111C. As a result, each C-shaped ring member 111C can function as an insulating probe for measuring plasma on the coating film 113C side.

Further, according to the present embodiment, the thickness of the dielectric plate 112C is 100 times or more the thickness of the second dielectric body. As a result, each C-shaped ring member 111C can function as an insulating probe for measuring plasma on the coating film 113C side.

Further, according to the present embodiment, the grooves are provided to form the plurality of cells surrounded by the plurality of resonators 101 fitted into the grooves. Each of at least two cells (e.g., the cells C31 and C33) among the plurality of cells (e.g., the cells C11 to C55) is provided with at least one resonator 101C including the C-shaped ring member 111C that also serves as the probe. As a result, the plasma information in the other cells can be estimated based on the plasma information measured in the two cells.

Further, according to the present embodiment, the probes are provided in a first cell (e.g., the cell C31) at the center of the resonator array structure 100 and at least one second cell (e.g., the cell C33) located on the outer peripheral side of the first cell. As a result, the plasma information in the other cells can be estimated based on the plasma information measured in the first and second cells.

Further, according to the present embodiment, the probes are provided in the first cell (e.g., the cell C31) among the plurality of cells and at least one second cell (e.g., the cell C33) located on a line (e.g., line A-A in FIG. 10) that passes through the first cell and is horizontal with respect to the base plate 120. As a result, the plasma information of the other cells located on this line can be estimated based on the plasma information measured in the first and second cells. Further, the plasma information of the plurality of cells located at other positions can be estimated based on the plasma information in the plurality of cells on this line.

Further, according to the present embodiment, the second cell is adjacent to the first cell or another second cell. As a result, the plasma information in the other cells located on the line that connects the first cell and the second cell can be easily estimated based on the plasma information measured in the first and second cells.

Further, according to the present embodiment, the C-shaped ring members 111C formed on both sides of the dielectric plate 112C also serve as the probes, and are connected to the conductors 122a provided at the bottom portions of the grooves, thereby obtaining electrical connection therebetween. The wirings 122 are connected to the conductors 122a. As a result, the wirings 122 can be simplified.

According to the present embodiment, a plasma measuring method is used for the plasma processing apparatus 1. The plasma processing apparatus 1 performs operations including: applying, in a state where the electromagnetic waves are supplied into the processing chamber 12, and plasma is generated in the plurality of cells (e.g., C11 to C55) formed by the plurality of resonators 101 that are included in the resonator array structure 100 located in the processing chamber 12 and are capable of resonating with the magnetic field component of the electromagnetic waves and have a size smaller than the wavelength of the electromagnetic waves, the AC voltage to the probe (the ring member 111C) that measures the plasma information and is implemented by at least one C-shaped ring member (the ring member 111C) among the C-shaped ring members (the ring members 111A to 111C) made of a conductor and included in the plurality of resonators 101; measuring the current flowing through the probe; and calculating the electron temperature and the electron density of the plasma in the cell where the probe is located based on the measured current. As a result, the plasma generated via the resonator array structure 100 can be quantitatively evaluated in its vicinity.

According to the present embodiment, the probes are provided in the plurality of cells, and the current is measured for each cell. As a result, plasma information for each cell can be calculated.

Further, according to the present embodiment, the C-shaped ring members 111C provided on both sides of one resonator 101 serve as the probes, and correspond to adjacent cells, respectively. The current value is measured as the sum of the values from the adjacent cells. The plasma electron temperature and the electron density are calculated based on the average value calculated from the sum of the values measured by the probes in the plurality of resonators 101 facing the respective cells. As a result, plasma information for each adjacent cell can be calculated while simplifying the wirings 122.

Further, according to the present embodiment, the number of probes and the number of cells are the same, and the plasma electron temperature and the electron density are calculated using the simultaneous equations of which number is equal to the number of probes. As a result, the plasma information of the cell can be calculated more accurately.

Further, according to the present embodiment, the number of probes is greater than the number of cells, and the plasma electron temperature and the electron density are calculated using the simultaneous equations of which number is equal to the number of probes. As a result, the plasma information of the cell can be calculated as an overdetermined system.

Further, according to the present embodiment, the number of probes is less than the number of cells, and the plasma electron temperature and the electron density are calculated using the simultaneous equations of which number is equal to the number of probes. As a result, the plasma information of the cell can be calculated as an underdetermined system.

It should be noted that the above-described embodiments are illustrative in all respects and are not restrictive. The above-described embodiments may be omitted, replaced, or changed in various forms without departing from the scope of the appended claims and the gist thereof.

Further, in the above-described embodiment, the resonator array structure 100 in which the plurality of resonators 101 are arranged in a lattice pattern has been described. However, the present disclosure is not limited thereto. For example, the resonator array structure may be formed by combining the plurality of strip-shaped (rectangular) resonators in which the plurality of resonators 101 arranged in the X-axis or Y-axis direction are integrated.

Further, in the above-described embodiment, the resonator array structure 100 is provided along the bottom surface 20a of the dielectric window 20. However, the present disclosure is not limited thereto. For example, the resonator array structure 100 may be embedded in the dielectric window 20 or spaced apart from the bottom surface 20a of the dielectric window 20. Further, for example, the resonator array structure 100 may be located along the upper surface of an electrostatic chuck 14c with the upper surface facing the processing space S, or may be spaced apart from the upper surface of the electrostatic chuck 14c. Further, for example, the resonator array structure 100 may be provided along the inner wall surface of the sidewall 12a of the processing chamber 12, or may be spaced apart from the inner wall surface of the sidewall 12a of the processing chamber 12.

Further, in the above-described embodiment, the output part of the microwave output device 16 may be connected to the base 14a that is a high-frequency electrode. In this case, the base 14a supplies the electromagnetic waves outputted from the microwave output device 16 to the processing space S via the electrostatic chuck 14c. Further, in such a configuration, the resonator array structure 100 may be embedded in the electrostatic chuck 14c.

In the above-described embodiment, a case has been described in which the resonator array structure 100 is formed by arranging the plurality of resonators 101 that can resonate with the magnetic field component of electromagnetic waves and have a size smaller than the wavelength of the electromagnetic waves in a lattice pattern along the bottom surface 20a of the dielectric window 20. However, the present disclosure is not limited thereto, and the plurality of resonators 101 may be arranged in any manner along the bottom surface 20a of the dielectric window 20. For example, the plurality of resonators 101 may be arranged at predetermined intervals along one direction. Further, for example, the resonator array structure may have a flat plate shape, and may be formed by arranging the plurality of resonators 101 in a lattice pattern along a plane parallel to the bottom surface 20a of the dielectric window 20. In other words, when viewed from the bottom surface 20a, the C-shaped ring members that appear through transmission are arranged side by side in a lattice pattern such that the C shape is visible. Further, in this case, the magnetic field generated by the antenna extends in a direction crossing the C-shaped ring members.

In the above embodiment, an inductively coupled coil was used as the antenna for injecting electromagnetic waves. However, the present disclosure is not limited thereto as long as the magnetic field can be generated in a direction penetrating through the ring members 111A to 111C of the plurality of resonators 101 of the resonator array structure 100. The antenna for injecting electromagnetic waves is not limited to an inductively coupled coil, and may be, e.g., any antenna or mechanism for injecting electromagnetic waves, such as a slot antenna, a monopole antenna, a capacitively coupled electrode, or a magnetron.

Further, in the above embodiments, the microwaves have been described as the electromagnetic waves for plasma excitation to be supplied to the processing space S. However, the present disclosure is not limited thereto. For example, electromagnetic waves in very high frequency (VHF) to ultra-high frequency (UHF) bands may be supplied as the electromagnetic waves for plasma generation to the processing space S.

Further, the present disclosure may employ the following configurations.

(1)

A plasma processing apparatus comprising:
a processing chamber providing a processing space;
an electromagnetic wave generator configured to generate plasma in the processing space by supplying electromagnetic waves;
a first dielectric body having a first surface facing the processing space;
an electromagnetic wave supply part configured to supply the electromagnetic waves to the processing space via the first dielectric body; and
a resonator array structure located in the processing chamber along the first surface of the first dielectric body,
wherein the resonator array structure includes a plurality of resonators that are capable of resonating with a magnetic field component of the electromagnetic waves and have a size smaller than a wavelength of the electromagnetic waves,
the plurality of resonators has a structure in which C-shaped ring members made of a conductor are provided on one surface of a dielectric plate, and
at least one of the C-shaped ring members serves as a probe for measuring information on the plasma.

(2)

The plasma processing apparatus of (1), further comprising:
a power supply part configured to apply an AC voltage to the probe through a wiring; and
an ammeter configured to measure a current value flowing through the probe.

(3)

The plasma processing apparatus of (2), wherein a frequency of the AC voltage is lower than a frequency of the electromagnetic waves supplied from the electromagnetic wave generator to the processing space.

(4)

The plasma processing apparatus of (3), wherein the frequency of the AC voltage is 100 kHz or less.

(5)

The plasma processing apparatus of (2) or (3), wherein the resonator array structure further includes:
a base plate having grooves on a surface facing the processing space; and
a pressing member configured to press the plurality of resonators fitted vertically into the grooves toward the base plate,
wherein the wiring is provided in the grooves and connected to the probe.

(6)

The plasma processing apparatus of any one of (1) to (5), wherein the C-shaped ring members are formed on both sides of the dielectric plate.

(7)

The plasma processing apparatus of any one of (1) to (6), wherein the C-shaped ring members are covered with a second dielectric body.

(8)

The plasma processing apparatus of (6), wherein the C-shaped ring members are formed on both sides of the dielectric plate and covered with a second dielectric body, and
a thickness of the dielectric plate between the C-shaped ring members formed on both sides of the dielectric plate is greater than a thickness of the second dielectric body covering the C-shaped ring members.

(9)

The plasma processing apparatus of (8), wherein the thickness of the dielectric plate is 100 times or more than the thickness of the second dielectric body.

(10)

The plasma processing apparatus of (5), wherein the groove is configured to enable a plurality of cells to be formed, the plurality of cells being surrounded by the plurality of resonators fitted in the groove, and
at least two of the plurality of cells each are provided with at least one resonator including the C-shaped ring member that also serves as the probe.

(11)

The plasma processing apparatus of (10), wherein the probe is provided in a first cell at a center of the resonator array structure and in at least one second cell located on an outer peripheral side of the first cell, among the plurality of cells.

(12)

The plasma processing apparatus of (11), wherein the probe is provided in the first cell and in at least one second cell, among the plurality of cells, the at least one second cell being located on a straight line that passes through the first cell and has a direction horizontal with respect to the base plate.

(13)

The plasma processing apparatus of (12), wherein the second cell is adjacent to the first cell or another second cell.

(14)

The plasma processing apparatus of (5), wherein the C-shaped ring members formed on both sides of the dielectric plate serve as the probe and are connected to conductors provided at bottom portions of the grooves so as to be electrically connected thereto, and
the wiring is connected to the conductors.

(15)

A plasma measuring method for a plasma processing apparatus, wherein the plasma processing apparatus performs operations of:
applying, in a state where electromagnetic waves are supplied into a processing chamber of the plasma processing apparatus, and plasma is generated in a plurality of cells formed by a plurality of resonators that are included in a resonator array structure located in the processing chamber and are capable of resonating with a magnetic field component of the electromagnetic waves and have a size smaller than a wavelength of the electromagnetic waves, an AC voltage to a probe for measuring information on the plasma that is implemented by at least one of C-shaped ring members made of a conductor and included in the plurality of resonators;
measuring a current value flowing through the probe; and
calculating, based on the measured current value, an electron temperature and an electron density of the plasma in the cell where the probe is located.

(16)

The plasma measuring method of (15), wherein the probe is provided in the plurality of cells, and
the current value is measured for each cell.

(17)

The plasma measuring method of (15), wherein probes are implemented by the C-shaped ring members provided on both sides of one of the resonators and respectively corresponds to adjacent cells;
the current value is measured as a sum of values from the respective adjacent cells; and
the electron temperature and the electron density of the plasma are calculated based on an average value calculated from sum values measured by the probes in the plurality of resonators facing the respective cells.

(18)

The plasma measuring method of (17), wherein the number of probes is equal to the number of cells, and
the electron temperature and the electron density of the plasma are calculated using simultaneous equations equal in number to the number of probes.

(19)

The plasma measuring method of (17), wherein the number of probes is greater than the number of cells, and
the electron temperature and the electron density of the plasma are calculated using simultaneous equations equal in number to the number of probes.

(20)

The plasma measuring method of (17), wherein the number of probes is less than the number of cells, and
the electron temperature and the electron density of the plasma are calculated using simultaneous equations equal in number to the number of probes.

1. A plasma processing apparatus comprising:
a processing chamber providing a processing space;
an electromagnetic wave generator configured to generate plasma in the processing space by supplying electromagnetic waves;
a first dielectric body having a first surface facing the processing space;
an electromagnetic wave supply part configured to supply the electromagnetic waves to the processing space via the first dielectric body; and
a resonator array structure located in the processing chamber along the first surface of the first dielectric body,
wherein the resonator array structure includes a plurality of resonators that are capable of resonating with a magnetic field component of the electromagnetic waves and have a size smaller than a wavelength of the electromagnetic waves,
the plurality of resonators has a structure in which C-shaped ring members made of a conductor are provided on one surface of a dielectric plate, and
at least one of the C-shaped ring members serves as a probe for measuring information on the plasma.

2. The plasma processing apparatus of claim 1, further comprising:
a power supply part configured to apply an AC voltage to the probe through a wiring; and
an ammeter configured to measure a current value flowing through the probe.

3. The plasma processing apparatus of claim 2, wherein a frequency of the AC voltage is lower than a frequency of the electromagnetic waves supplied from the electromagnetic wave generator to the processing space.

4. The plasma processing apparatus of claim 3, wherein the frequency of the AC voltage is 100 KHz or less.

5. The plasma processing apparatus of claim 2, wherein the resonator array structure further includes:
a base plate having grooves on a surface facing the processing space; and
a pressing member configured to press the plurality of resonators fitted vertically into the grooves toward the base plate,
wherein the wiring is provided in the grooves and connected to the probe.

6. The plasma processing apparatus of claim 1, wherein the C-shaped ring members are formed on both sides of the dielectric plate.

7. The plasma processing apparatus of claim 1, wherein the C-shaped ring members are covered with a second dielectric body.

8. The plasma processing apparatus of claim 6, wherein the C-shaped ring members are formed on both sides of the dielectric plate and covered with a second dielectric body, and
a thickness of the dielectric plate between the C-shaped ring members formed on both sides of the dielectric plate is greater than a thickness of the second dielectric body covering the C-shaped ring members.

9. The plasma processing apparatus of claim 8, wherein the thickness of the dielectric plate is 100 times or more than the thickness of the second dielectric body.

10. The plasma processing apparatus of claim 5, wherein the groove is configured to enable a plurality of cells to be formed, the plurality of cells being surrounded by the plurality of resonators fitted in the groove, and
at least two of the plurality of cells each are provided with at least one resonator including the C-shaped ring member that also serves as the probe.

11. The plasma processing apparatus of claim 10, wherein the probe is provided in a first cell at a center of the resonator array structure and in at least one second cell located on an outer peripheral side of the first cell, among the plurality of cells.

12. The plasma processing apparatus of claim 11, wherein the probe is provided in the first cell and in at least one second cell, among the plurality of cells, the at least one second cell being located on a straight line that passes through the first cell and has a direction horizontal with respect to the base plate.

13. The plasma processing apparatus of claim 12, wherein the second cell is adjacent to the first cell or another second cell.

14. The plasma processing apparatus of claim 5, wherein the C-shaped ring members formed on both sides of the dielectric plate serve as the probe and are connected to conductors provided at bottom portions of the grooves so as to be electrically connected thereto, and
the wiring is connected to the conductors.

15. A plasma measuring method for a plasma processing apparatus, wherein the plasma processing apparatus performs operations of:
applying, in a state where electromagnetic waves are supplied into a processing chamber of the plasma processing apparatus, and plasma is generated in a plurality of cells formed by a plurality of resonators that are included in a resonator array structure located in the processing chamber and are capable of resonating with a magnetic field component of the electromagnetic waves and have a size smaller than a wavelength of the electromagnetic waves, an AC voltage to a probe for measuring information on the plasma that is implemented by at least one of C-shaped ring members made of a conductor and included in the plurality of resonators;
measuring a current value flowing through the probe; and
calculating, based on the measured current value, an electron temperature and an electron density of the plasma in the cell where the probe is located.

16. The plasma measuring method of claim 15, wherein the probe is provided in the plurality of cells, and
the current value is measured for each cell.

17. The plasma measuring method of claim 15, wherein probes are implemented by the C-shaped ring members provided on both sides of one of the resonators and respectively corresponds to adjacent cells;
the current value is measured as a sum of values from the respective adjacent cells; and
the electron temperature and the electron density of the plasma are calculated based on an average value calculated from sum values measured by the probes in the plurality of resonators facing the respective cells.

18. The plasma measuring method of claim 17, wherein the number of probes is equal to the number of cells, and
the electron temperature and the electron density of the plasma are calculated using simultaneous equations equal in number to the number of probes.

19. The plasma measuring method of claim 17, wherein the number of probes is greater than the number of cells, and
the electron temperature and the electron density of the plasma are calculated using simultaneous equations equal in number to the number of probes.

20. The plasma measuring method of claim 17, wherein the number of probes is less than the number of cells, and
the electron temperature and the electron density of the plasma are calculated using simultaneous equations equal in number to the number of probes.
